(19) United States
(12) Patent Application Publication
(10) Pub. No.: US 2025/0038062 A1
(43) Pub. Date: Jan. 30, 2025

(54) SUBSTRATE STRUCTURE, SEMICONDUCTOR STRUCTURE AND METHOD OF MANUFACTURING SUBSTRATE STRUCTURE

(71) Applicant: Enkris Semiconductor (Wuxi), Ltd., Wuxi city (CN)

(72) Inventor: Kai CHENG, Wuxi city (CN)

(21) Appl. No.: 18/783,441

(22) Filed: Jul. 25, 2024

(30) Foreign Application Priority Data
Jul. 26, 2023 (CN) 202310926371.1

(51) Int. Cl. H01L 23/367; H01L 21/304; H01L 29/06

(52) U.S. Cl. CPC H01L 23/367; H01L 21/3043; H01L 29/0607; H01L 29/0657

(57) ABSTRACT

The present disclosure provides a substrate structure, a semiconductor structure, and a method of manufacturing the substrate structures. The substrate structure includes: a base substrate, an insulation layer and a growth substrate on the base substrate in sequence; a groove provided on a side of the base substrate away from the growth substrate, where the groove penetrates at least one part of the base substrate. The present disclosure can improve the heat-dissipation performance of the substrate structure.

### CROSS REFERENCE TO RELATED APPLICATIONS

This application claims priority to Chinese Patent Application No. 2023109263711 filed on Jul. 26, 2023, the entire content of which is incorporated herein by reference.

### TECHNICAL FIELD

The present disclosure relates to the technical field of semiconductors and in particular, to a substrate structure, a semiconductor structure and a method of manufacturing the substrate structure.

### BACKGROUND

With the continuous advancement of integrated circuit manufacturing processes, the size of the semiconductor devices is becoming smaller and smaller, followed by a large number of problems that arise when the device size approaches the physical limit, which has led the industry to look for the solutions other than simply reducing the device size to further improve the device performance. Silicon-on-insulator (SOI) has been widely studied and used by the industry as an important direction of development. Compared with the traditional bulk silicon structure, the characteristic of SOI is that there is an insulation layer under a very thin monocrystalline silicon layer at the surface, mainly using silicon oxide as the insulating material. Under the insulation layer is the traditional bulk silicon structure, and the function of the traditional bulk silicon structure is to provide the mechanical support to the upper structure. The SOI, without changing the device size, greatly reduces the leakage current of the device, thereby greatly improving the performance of the device.

However, compared with the devices that do not use the silicon substrate on the insulation layer, the devices using the silicon substrate on the insulation layer generally suffer from a problem of poor heat-dissipation, and the excessive heat accumulation may lead to a decline of the saturation-region drain current (Idsat). In addition, the devices using the silicon substrate on the insulation layer may also be affected by the backside bias effect (also known as the substrate bias effect), thereby changing the breakdown voltage of the metal-oxide-semiconductor field-effect transistor (MOSFET).

### SUMMARY

A purpose of the present disclosure is providing a diode structure, a HEMT structure a substrate structure and a method of manufacturing the substrate structure, which can improve the heat-dissipation performance of the substrate structure.

According to an aspect of the present disclosure, a substrate structure is provided, including:
a base substrate, and an insulation layer and a growth substrate on the base substrate in sequence; and
grooves in a side of the base substrate away from the growth substrate, where the grooves penetrate at least one part of the base substrate, and at least two of the grooves are different in depth or opening width.

Optionally, a density of the grooves in a central region of the base substrate is greater than a density of the grooves in an edge region of the base substrate.

Optionally, along a direction from a center of the base substrate to an edge of the base substrate, depths and/or opening widths of the grooves gradually decrease.

Optionally, the substrate structure includes unit regions, each of the unit regions includes at least two unit sub-regions, and each of the at least two unit sub-regions includes at least one of the grooves; and
in one of the unit regions, the grooves in respective unit sub-regions are different in size.

Optionally, the grooves include a first portion in the base substrate, a second portion in the insulation layer, and a third portion in the growth substrate;
where an opening width of the first portion of the groove is greater than an opening width of the second portion and an opening width of the third portion of the groove.

Optionally, in a direction from the base substrate to the growth substrate,
the opening widths of the first portion, the second portion and the third portion of one of the grooves remain unchanged; or
the opening widths of the first portion, the second portion and the third portion of the groove gradually decrease; or
the opening width of the first portion of the groove gradually decreases, and the opening width of the third portion of the groove remains unchanged; or
the opening width of the first portion of the groove remains unchanged, and the opening width of the third portion of the groove gradually decreases.

Optionally, one of the grooves penetrates the base substrate and the insulation layer, and a bottom of the groove is at a surface of the growth substrate close to the base substrate; or
one of the grooves penetrates the base substrate and the insulation layer, and the groove penetrates a part of the growth substrate; or
one of the grooves penetrates the base substrate, the insulation layer and the growth substrate.

Optionally, the growth substrate is a superjunction structure, the superjunction structure includes n-type semiconductor structures and p-type semiconductor structures, and the n-type semiconductor structures and the p-type semiconductor structures are alternately distributed along a direction parallel to the growth substrate.

Optionally, the substrate structure further includes:
a protective layer on a side of the base substrate away from the growth substrate, where the protective layer has openings exposing the base substrate, and the openings correspond to the grooves one by one.

Optionally, the substrate structure further includes:
a heat-dissipation layer covering the inner wall of the grooves.

According to another aspect of the present disclosure, semiconductor structure is provided, including:
the substrate structure according to any one of the above;
a device structure on the substrate structure, where the device structure is on a side of the growth substrate away from the base substrate, and
the semiconductor structure is any one of a high electron mobility transistor device, a vertical power device, a radio frequency device and a light emitting diode device.

According to another aspect of the present disclosure, a method of manufacturing the semiconductor structure is provided, including:
providing a base substrate;
forming an insulation layer and a growth substrate on the base substrate in sequence; and
forming grooves at a side of the base substrate away from the growth substrate, where the grooves penetrate at least one part of the base substrate, and at least two of the grooves are different in depth or opening width.

Optionally, along a direction from a center of the base substrate to an edge of the base substrate, depths or opening widths of the grooves gradually decrease.

Optionally, a density of the grooves in a central region of the base substrate is greater than a density of the grooves in an edge region of the base substrate.

Optionally, the substrate structure includes unit regions, each of the unit regions includes at least two unit sub-regions, and each of the at least two unit sub-regions includes at least one of the grooves; and
in one of the unit regions, the grooves in respective unit sub-regions are different in size.

Optionally, one of the grooves includes a first portion in the base substrate, a second portion in the insulation layer, and a third portion in the growth substrate;
where an opening width of the first portion of the groove is greater than an opening width of the second portion and an opening width of the third portion of the one of the grooves.

Optionally, in a direction from the base substrate to the growth substrate,
the opening widths of the first portion, the second portion and the third portion of the groove remain unchanged; or
the opening widths of the first portion, the second portion and the third portion of the groove gradually decrease; or
the opening width of the first portion of the groove gradually decreases, and the opening width of the third portion of the groove remains unchanged; or
the opening width of the first portion of the groove remains unchanged, and the opening width of the third portion of the groove gradually decreases.

Optionally, one of the grooves penetrates the base substrate and the insulation layer, and a bottom of the groove is at a surface of the growth substrate close to the base substrate; or
one of the grooves penetrates the base substrate and the insulation layer, and the groove penetrates a part of the growth substrate; or
one of the grooves penetrates the base substrate, the insulation layer and the growth substrate.

Optionally, forming a superjunction structure in the growth substrate, the superjunction structure includes n-type semiconductor structures and p-type semiconductor structures, and the n-type semiconductor structures and the p-type semiconductor structures are alternately distributed along a direction parallel to the growth substrate.

Optionally, forming the grooves each penetrating at least one part of the base substrate the base substrate includes:
forming a protective layer on the side of the base substrate away from the growth substrate;
forming openings exposing the base substrate on the protective layer;
etching the base substrate, using the protective layer with the openings as a mask, to form the grooves.

Optionally, after forming the grooves at a side of the base substrate away from the growth substrate, the method further includes:
forming a heat-dissipation layer covering the inner wall of the grooves.

### BRIEF DESCRIPTION OF DRAWINGS

FIG. 1 is a schematic diagram of a structure after forming a protective layer according to an embodiment of the present disclosure.

FIGS. 2-13 are schematic diagrams of structures after forming a groove according to an embodiment of the present disclosure.

FIG. 14 is a schematic diagram of a substrate structure manufactured according to an embodiment of the present disclosure.

FIG. 15 is a schematic diagram of a substrate structure manufactured according to an embodiment of the present disclosure.

FIG. 16 is a schematic diagram of a substrate structure manufactured according to an embodiment of the present disclosure.

FIG. 17 is a schematic diagram of a semiconductor structure manufactured according to an embodiment of the present disclosure.

FIG. 18 is a schematic diagram of a semiconductor structure manufactured according to an embodiment of the present disclosure.

### EXPLANATION OF REFERENCE SIGNS

100, unit region; 100a, unit sub-region; 101, base substrate; 102, insulation layer; 103, growth substrate; 1031, n-type semiconductor structure; 1032, p-type semiconductor structure; 104, groove; 104a, first portion; 104b, second portion; 104c, third portion; 2, heterojunction structure; 201, channel layer; 202, barrier layer; 3, gate electrode; 4, source electrode; 5, drain electrode; 6, protective layer; 601, opening; 7, nucleation layer; 8, heat-dissipation layer; 9, buffer layer; 10, first electrode; 11, second electrode.

### DETAILED DESCRIPTION

Exemplary embodiments will be described herein in detail, examples of which are represented in the accompanying drawings. When the following descriptions involve the drawings, like numerals in different drawings refer to like or similar elements unless otherwise indicated. The embodiments described in the following exemplary embodiments do not represent all embodiments consistent with the present application. Rather, they are only examples of devices and methods that are consistent with some aspects of the present application, as detailed in the appended claims.

The terms used in the present disclosure are for the purpose of describing specific embodiments only and are not intended to limit the present disclosure. Unless otherwise defined, technical terms or scientific terms used in the present disclosure shall have their ordinary meanings as understood by those of ordinary skills in the field to which the present disclosure belongs. The “first”, “second” and similar words used in the specification and claims of the present disclosure do not indicate any order, quantity or importance, but are only used to distinguish different components. Similarly, similar words such as “a” or “an” do not mean quantity limitation, but mean that there is at least one. “Multiple” or “a plurality of” means two or more. Unless otherwise specified, similar words such as “front”, “rear”, “lower” and/or “upper” are only for convenience of explanation, and are not limited to a position or a spatial orientation. Similar words such as “include” or “comprise” mean that the elements or objects appear before “include” or “comprise” cover the elements or objects listed after “include” or “comprise” and their equivalents, but do not exclude other elements or objects. Similar words such as “connect” or “couple” are not limited to physical or mechanical connection, but may include electrical connection, whether direct or indirect. Singular forms “a”, “the” and “said” used in the specification of the present disclosure and the appended claims are also intended to include plural forms, unless the context clearly indicates other meaning. It should also be understood that the term “and/or” as used herein refers to and includes any or all possible combinations of one or more associated listed items.

### Embodiment 1

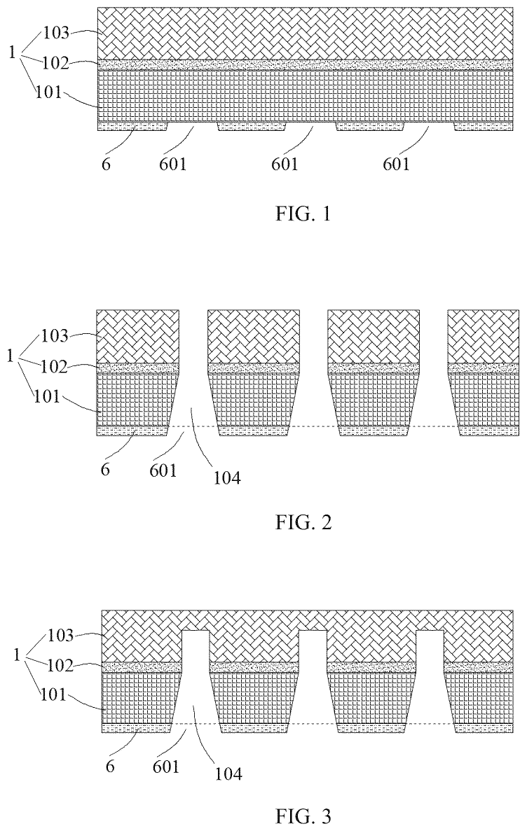

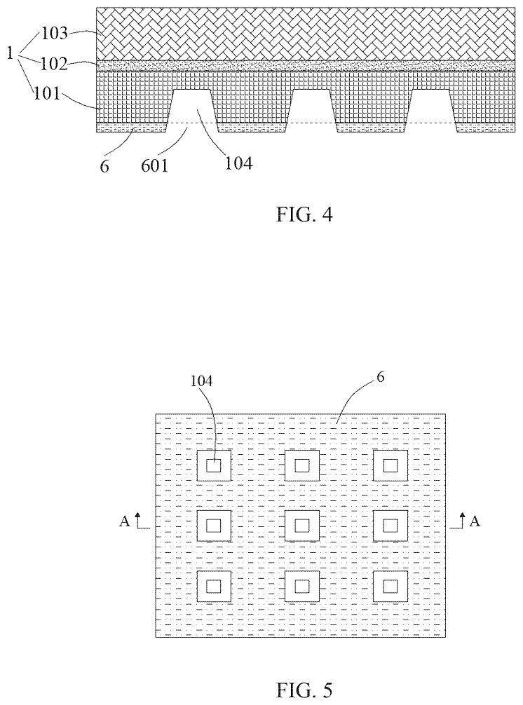

According to an Embodiment 1 of the present disclosure, a substrate structure and a method of manufacturing the substrate structure are provided. FIG. 1 is a schematic diagram of a structure after forming a protective layer 6 according to an Embodiment 1 of the present disclosure. FIGS. 2-13 are schematic diagrams of structures after forming a groove 104 according to an Embodiment 1 of the present disclosure. FIG. 2 is an A-A cross-sectional view of the structure shown in FIG. 5. The method of manufacturing the substrate structure may include step S100 to step S110.

In step S100: a base substrate 101 is provided, and an insulation layer 102 and a growth substrate 103 are formed on the base substrate 101 in sequence.

In step S110: a groove 104 is formed on a side of the base substrate 101 away from the growth substrate 103, where the groove 104 penetrates at least one part of the base substrate 101.

In the substrate structure manufactured in this embodiment, since the substrate structure is provided with a groove 104 that penetrates at least one part of the base substrate 101, which is equivalent to reducing the average thickness of the substrate structure, thereby improving the heat-dissipation performance of the substrate structure. When the substrate structure is applied to a semiconductor structure, the excessive heat accumulation in the semiconductor structure can be avoided, thereby alleviating the problem for the decline of the saturation-region drain current caused by the excessive heat accumulation.

According to the embodiments of the present disclosure, each step of the method of manufacturing the substrate structure will be described in detail as follows.

In step S100, the base substrate 101 may be made of 100 type monocrystalline silicon with (100) crystal plane, and the growth substrate 103 may be made of monocrystalline silicon with (111) crystal plane. The insulation layer 102 is between the base substrate 101 and the growth substrate 103, and made of the insulating material, such as SiO₂. In other embodiments, the base substrate 101 may also be made of any one of SiC, AlN, Al₂O₃ or a ceramic substrate, and the growth substrate may be made of any one of SiC, AlN or Al₂O₃, which is not limited in this embodiment.

In step S110: a groove 104 is formed on a side of the base substrate 101 away from the growth substrate 103, where the groove 104 penetrates at least one part of the base substrate 101. The groove 104 penetrates at least one part of the base substrate 101, that is, the groove 104 may only penetrate a part of the base substrate 101; or, the groove 104 penetrates the base substrate 101 and the bottom of the groove 104 is at the surface of the insulation layer 102 close to the base substrate 101; or, the groove 104 penetrates the base substrate 101 and the insulation layer 102, and the bottom of the groove 104 is at the surface of the growth substrate 103 close to the base substrate 101; or, the groove 104 penetrates the base substrate 101 and the insulation layer 102 and penetrates a part of the growth substrate 103; or, the groove 104 completely penetrates the base substrate 101, the insulation layer 102 and the growth substrate 103. The depth of the groove 104 is not limited in the present disclosure. As shown in FIG. 2, the groove 104 is equivalent to a through hole penetrating the base substrate 101, the insulation layer 102 and the growth substrate 103. Alternatively, as shown in FIG. 3, the groove 104 penetrates the base substrate 101 and the insulation layer 102 and penetrates a part of the growth substrate 103, that is, the bottom of the groove 104 extends into the growth substrate 103. As shown in FIG. 4, the groove 104 may, of course, only penetrate a part of the base substrate 101. It can be understood that the heat-dissipation capabilities are different because of the different depths of the grooves 104.

The number of the grooves 104 may be multiple, and the grooves 104 may be distributed apart. Furthermore, the grooves 104 may be evenly distributed. As shown in FIG. 8, which is a bottom view of the substrate in an optional embodiment, the density of grooves 104 in the central region of the base substrate 101 is greater than the density of grooves 104 in the edge region of the base substrate 101. The depths of the grooves 104 may be the same. Among the grooves 104, at least two of the grooves 104 may have different depths. For example, the depths of the respective grooves 104 may be different. The cross-sectional shape of the groove 104 may be a polygon, such as a strip, a triangle, a square, a rectangle, a trapezoid, etc. The cross-sectional shape of the groove 104 may also be a circular, an oval, etc., and the cross-section is parallel to the base substrate 101. In some embodiments, in the direction from the base substrate 101 to the growth substrate 103, the opening widths of the groove 104 remain unchanged or gradually decrease. Optionally, at least two of the grooves 104 have different depths or different opening widths. As shown in FIG. 9, FIG. 9 is an A-A cross-sectional view of the structure shown in FIG. 5 in an optional embodiment, in the direction from the center of the base substrate 101 to the edge of the base substrate 101, the depths and/or the opening widths of the grooves 104 gradually decrease, and in this way, the heating uniformity of the substrate structure during the epitaxial process can be balanced, to improve the crystal quality of the semiconductor layer of the device structure formed on the substrate structure, thereby improving the performance of the device structure.

As shown in FIGS. 10 to 13, in an optional embodiment, the groove 104 includes a first portion 104a located in the base substrate 101, a second portion 104b located in the insulation layer 102 and a third portion 104c located in the growth substrate 103. The opening width of the first portion 104a of the groove 104 is greater than the opening widths of the second portion 104b and the third portion 104c. Optionally, as shown in FIG. 10, in the direction from the base substrate 101 to the growth substrate 103, the opening widths of the first portion 104a, the second portion 104b and the third portion 104c remain unchanged. Optionally, as shown in FIG. 11, in the direction from the base substrate 101 to the growth substrate 103, the opening widths of the first portion 104a, the second portion 104b and the third portion 104c gradually decrease. Optionally, as shown in FIG. 12, in the direction from the base substrate 101 to the growth substrate 103, the opening width of the first portion 104a gradually decreases, and the opening widths of the second portion 104b and the third portion 104c remain unchanged. Optionally, as shown in FIG. 13, in the direction from the base substrate 101 to the growth substrate 103, the opening width of the first portion 104a remain unchanged, the opening width of the second portion 104b remain unchanged, and the opening width of the third portion 104c gradually decreases.

As shown in FIGS. 6 to 7, FIG. 7 is a B-B cross-sectional view of the structure shown in FIG. 6. In an optional embodiment, the substrate structure includes several unit regions 100, each unit region 100 includes at least two unit sub-regions 100a, and each unit sub-region 100a includes at least one groove 104. In one unit region 100, the grooves 104 in respective unit sub-regions 100a are different in size. The size of the at least one groove in the unit sub-region 100a refers to the ratio of the total volume of the groove 104 of the unit sub-region 100a to the volume of the material of the base substrate 101 in the unit sub-region 100a. In some embodiments, in one unit sub-region 100a, the grooves 104 of the respective unit sub-regions 100a are different in depth, and/or width, and/or opening density.

Specifically, the above-mentioned step S110 may include: forming a protective layer 6 on the side of the base substrate 101 away from the growth substrate 103; forming an opening 601 exposing the base substrate 101 in the protective layer 6; and etching the base substrate 101, using the protective layer 6 with the opening 601 as a mask; to form the groove 104. The protective layer may be made of the insulating material, such as SiO₂, SiN or etc. The mask may be manufactured by the vapor deposition. The opening 601 may be formed by the photolithography process. The present disclosure can etch the silicon-on-insulator 1 through a wet etching process, and the formed groove 104 is connected to the opening 601. The number of the openings 601 may be multiple to form the grooves 104 corresponding to the openings 601 one-to-one.

### Embodiment 2

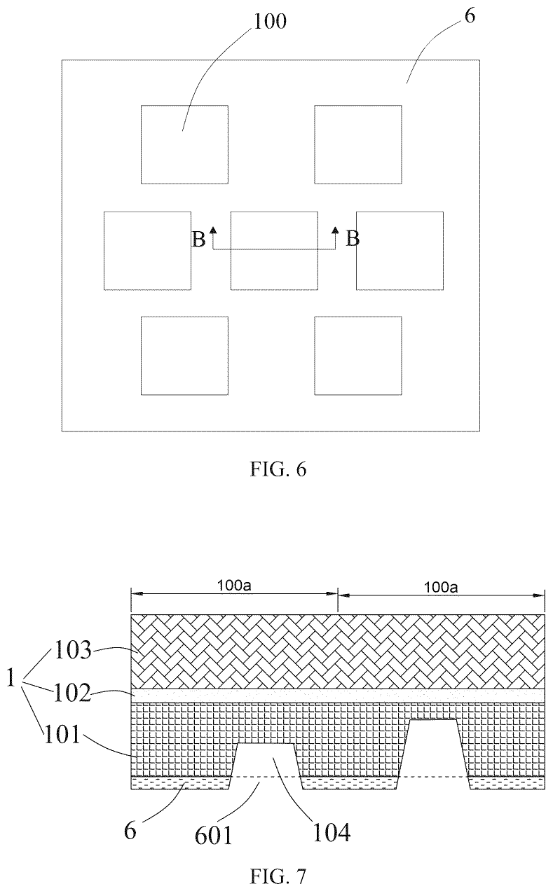

FIG. 14 is a schematic diagram of a substrate structure manufactured according to an Embodiment 2 of the present disclosure. The substrate structure and the method of manufacturing the substrate structure in the Embodiment 2 of the present disclosure are substantially the same as the substrate structure and the method of manufacturing the substrate structure in the Embodiment 1 of the present disclosure, and the difference includes that the super junction structure is manufactured in the growth substrate 103. The super junction structure includes an n-type semiconductor structure 1031 and a p-type semiconductor structure 1032. The n-type semiconductor structure 1031 and the p-type semiconductor structure 1032 are alternately distributed along the direction parallel to the growth substrate 103 to improve the vertically integrated voltage of the device structure formed on the substrate structure.

### Embodiment 3

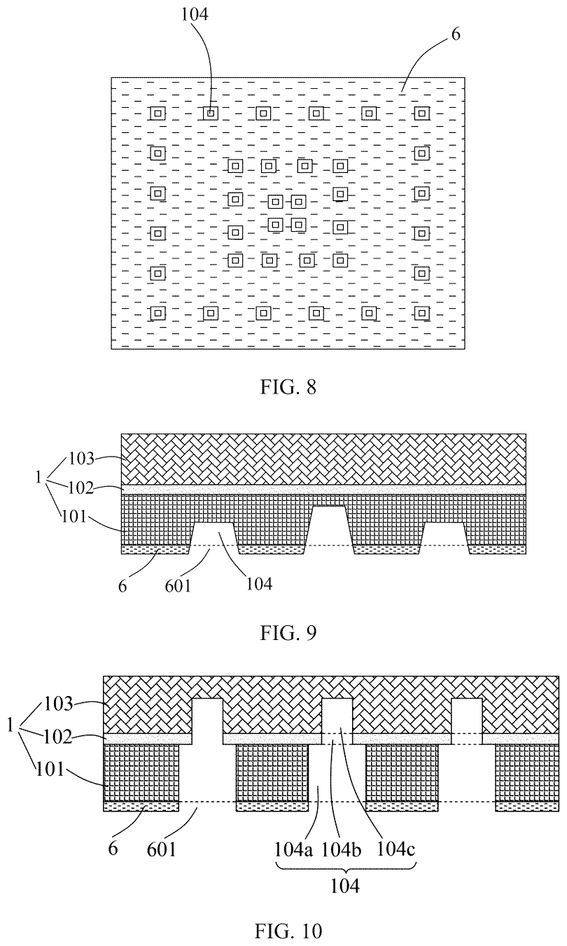

FIG. 15 is a schematic diagram of a substrate structure manufactured according to an Embodiment 3 of the present disclosure. The substrate structure and the method of manufacturing the substrate structure in the Embodiment 3 of the present disclosure are substantially the same as the substrate structure and the method of manufacturing the substrate structure in any one of the embodiments 1 and 2 of the present disclosure, and the difference includes that, the substrate structure further includes a nucleation layer 7 and a buffer layer 9. The nucleation layer 7 is disposed on a side of the growth substrate 103 away from the base substrate 101, and the buffer layer 9 is disposed on a side of the nucleation layer 7 away from the base substrate 101. The buffer layer 9 may be an n-type buffer layer 9, or may, of course, be a p-type buffer layer 9. The buffer layer 9 may be made of a group III-V compound, such as AlN, GaN, AlGaN, AlInGaN, etc. The buffer layer 9 may be formed by the epitaxial growth. In other embodiments, the nucleation layer 7 is optional, that is, the buffer layer 9 may be formed directly on the substrate structure.

### Embodiment 4

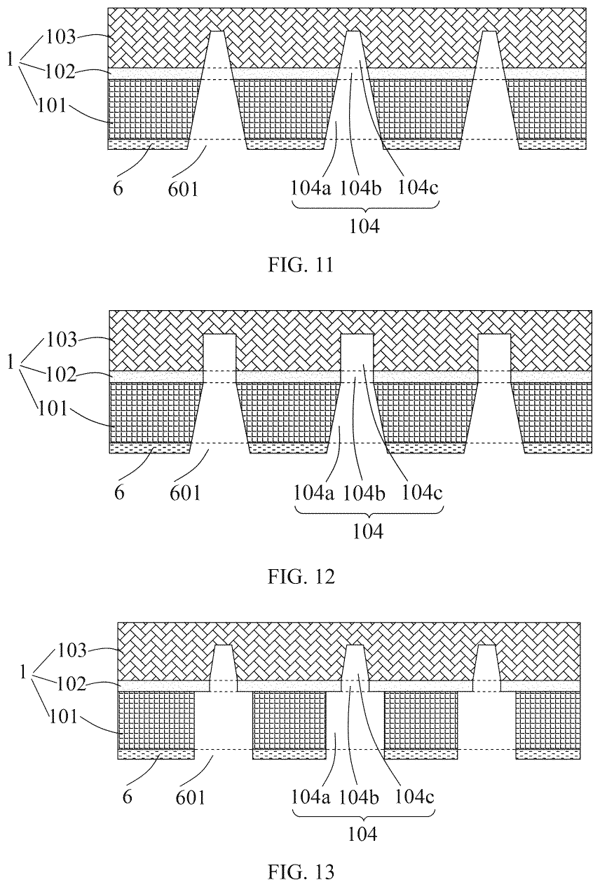

FIG. 16 is a schematic diagram of a substrate structure manufactured according to an Embodiment 4 of the present disclosure. The substrate structure and the method of manufacturing the substrate structure in the Embodiment 4 of the present disclosure are substantially the same as the substrate structure and the method of manufacturing the substrate structure in any one of the embodiments 1 to 3 of the present disclosure, and the difference includes that, the manufacturing method further includes: forming a heat-dissipation layer 8 covering the inner wall of the groove to further improve the heat-dissipation performance of the substrate structure. The heat-dissipation layer 8 may be made of AlN, GaN, AlGaN, AlInGaN or etc. The heat-dissipation layer 8 can be formed by the epitaxial growth.

### Embodiment 5

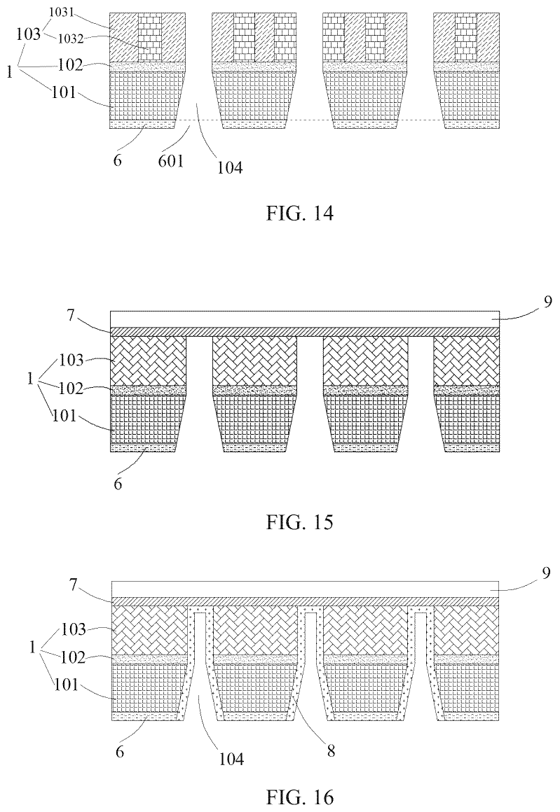

FIG. 17 is a schematic diagram of a semiconductor structure according to an Embodiment 5 of the present disclosure. The semiconductor structure in Embodiment 5 of the present disclosure includes the substrate structure of any one of the Embodiments 1 to 4 of the present disclosure. According to this embodiment, the semiconductor structure is a high electron mobility transistor device. The semiconductor structure further includes a device structure formed on the growth substrate 103, and the device structure includes a heterojunction structure 2, a gate electrode 3, a source electrode 4 and a drain electrode 5. The heterojunction structure 2 is disposed on the side of the growth substrate 103 away from the base substrate 101. The heterojunction structure 2 includes a source region, a drain region, and a gate region between the source region and the drain region. The gate electrode 3 is on the gate region. The source electrode 4 is on the source region. The drain electrode 5 is on the drain region. The heterojunction structure 2 may include a channel layer 201 and a barrier layer 202. The channel layer 201 is between the barrier layer 202 and the substrate structure. For a substrate structure provided with a buffer layer 9, the heterojunction structure 2 may be disposed on the buffer layer 9.

### Embodiment 6

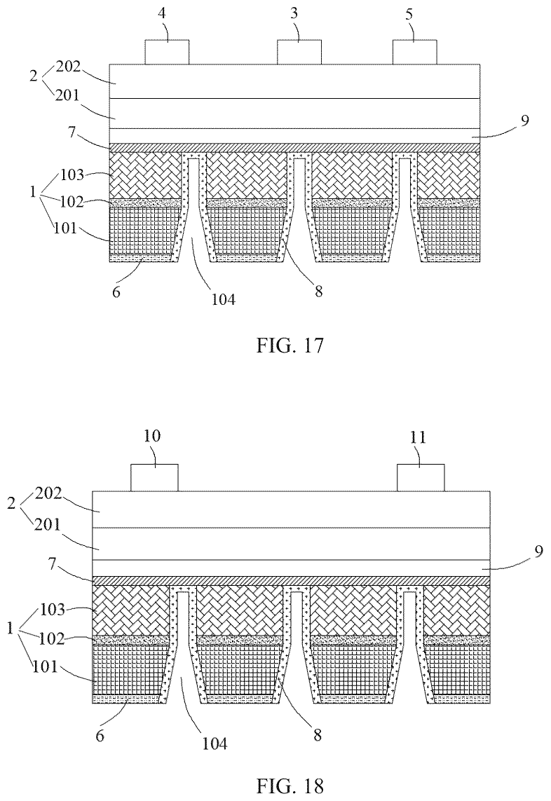

FIG. 18 is a schematic diagram of a semiconductor structure according to an Embodiment 6 of the present disclosure. The semiconductor structure in Embodiment 6 of the present disclosure includes the substrate structure of any one of the Embodiments 1 to 4 of the present disclosure. According to this embodiment, the semiconductor structure is a diode structure. The semiconductor structure further includes a device structure formed on the growth substrate 103, and the device structure includes a heterojunction structure 2, a first electrode 10 and a second electrode 11. The heterojunction structure 2 is disposed on the side of the growth substrate 103 away from the base substrate 101. The first electrode 10 and the second electrode 11 are disposed on the heterojunction structure 2. The first electrode 10 is in Schottky contact with the heterojunction structure 2, and the second electrode 11 is in Ohmic contact with the heterojunction structure 2. The heterojunction structure 2 may include a channel layer 201 and a barrier layer 202. The channel layer 201 is between the barrier layer 202 and the substrate structure. For a substrate structure provided with a buffer layer 9, the heterojunction structure 2 may be disposed on the buffer layer 9. In other embodiments, the semiconductor structure may be any one of a high electron mobility transistor device, a vertical power device, a radio frequency device, and a light-emitting diode device.

According to the substrate structure, the semiconductor structure and the method of manufacturing the substrate structure according to the embodiments of the present disclosure, since the substrate structure is provided with the grooves each penetrating at least a part of the base substrate, that is equivalent to reducing the average thickness of the substrate structure, thereby improving the heat-dissipation performance of the substrate structure. When the substrate structure is applied to a semiconductor structure, the excessive heat accumulation in the semiconductor structure can be avoided, thereby alleviating the problem of the drain current decline in the saturation region caused by the excessive heat accumulation.

The above are some embodiments of the present disclosure, and they do not limit the present disclosure in any form. Although the present disclosure has been disclosed in the preferred embodiments, they are not used to limit the present disclosure. Those skilled in the art can make some changes or modifies into an equivalent embodiment by using the technical content disclosed above without departing from the scope of the technical solution of the present disclosure. So long as the content does not depart from the technical solution of the present disclosure, any simple changes, equivalent changes or modifications made to the above embodiments according to the technical essence of the present disclosure shall all belong to the scope of the technical solution of the present disclosure.

What is claimed is:

1. A substrate structure, comprising:
a base substrate;
an insulation layer and a growth substrate on the base substrate in sequence; and
grooves in a side of the base substrate away from the growth substrate, wherein the grooves each penetrate at least one part of the base substrate, and at least two of the grooves are different in depth or opening width.

2. The substrate structure according to claim 1, wherein a density of the grooves in a central region of the base substrate is greater than a density of the grooves in an edge region of the base substrate.

3. The substrate structure according to claim 1, wherein along a direction from a center of the base substrate to an edge of the base substrate, depths and/or opening widths of the grooves gradually decrease.

4. The substrate structure according to claim 1, wherein the substrate structure comprises unit regions, each of the unit regions comprises at least two unit sub-regions, and each of the at least two unit sub-regions comprises at least one of the grooves; and
in one of the unit regions, the grooves in respective unit sub-regions are different in size.

5. The substrate structure according to claim 1, wherein one of the grooves comprises a first portion in the base substrate, a second portion in the insulation layer, and a third portion in the growth substrate;
wherein an opening width of the first portion of the groove is greater than an opening width of the second portion and an opening width of the third portion of the groove.

6. The substrate structure according to claim 5, wherein in a direction from the base substrate to the growth substrate,
the opening widths of the first portion, the second portion and the third portion of the groove remain unchanged; or
the opening widths of the first portion, the second portion and the third portion of the groove gradually decrease; or
the opening width of the first portion of the groove gradually decreases, and the opening width of the third portion of the groove remains unchanged; or
the opening width of the first portion of the groove remains unchanged, and the opening width of the third portion of the groove gradually decreases.

7. The substrate structure according to claim 1, wherein
one of the grooves penetrates the base substrate and the insulation layer, and a bottom of the groove is at a surface of the growth substrate close to the base substrate; or
one of the grooves penetrates the base substrate and the insulation layer, and the groove penetrates a part of the growth substrate; or
one of the grooves penetrates the base substrate, the insulation layer and the growth substrate.

8. The substrate structure according to claim 1, wherein the growth substrate is a superjunction structure, the superjunction structure comprises n-type semiconductor structures and p-type semiconductor structures, and the n-type semiconductor structures and the p-type semiconductor structures are alternately distributed along a direction parallel to the growth substrate.

9. The substrate structure according to claim 1, further comprising:
a protective layer on a side of the base substrate away from the growth substrate, wherein the protective layer has openings exposing the base substrate, and the openings correspond to the grooves one by one.

10. The substrate structure according to claim 1, further comprising:
a heat-dissipation layer covering the inner wall of the grooves.

11. A semiconductor structure, comprising:
the substrate structure according to claim 1; and
a device structure on the substrate structure, wherein the device structure is on a side of the growth substrate away from the base substrate; and
wherein the semiconductor structure is any one of a high electron mobility transistor device, a vertical power device, a radio frequency device and a light emitting diode device.

12. A method of manufacturing a substrate structure, comprising:
providing a base substrate;
forming an insulation layer and a growth substrate on the base substrate in sequence; and
forming grooves at a side of the base substrate away from the growth substrate, wherein the grooves each penetrate at least one part of the base substrate, and at least two of the grooves are different in depth or opening width.

13. The method according to claim 12, wherein along a direction from a center of the base substrate to an edge of the base substrate, depths and/or opening widths of the grooves gradually decrease.

14. The method according to claim 12, wherein a density of the grooves in the central region of the base substrate is greater than a density of the grooves in the edge region of the base substrate.

15. The method according to claim 12, wherein the substrate structure comprises unit regions, each of the unit regions comprises at least two unit sub-regions, and each of the at least two unit sub-regions comprises at least one of the grooves; and
in one of the unit regions, the grooves in respective unit sub-regions are different in size.

16. The method according to claim 12, wherein one of the grooves comprises a first portion in the base substrate, a second portion in the insulation layer, and a third portion in the growth substrate; and
wherein an opening width of the first portion of the groove is greater than an opening width of the second portion and an opening width of the third portion of the groove.

17. The method according to claim 16, wherein in a direction from the base substrate to the growth substrate,
the opening widths of the first portion, the second portion and the third portion of the groove remain unchanged; or
the opening widths of the first portion, the second portion and the third portion of the groove gradually decrease; or
the opening width of the first portion of the groove gradually decreases, and the opening width of the third portion of the groove remains unchanged; or
the opening width of the first portion of the groove remains unchanged, and the opening width of the third portion of the groove gradually decreases.

18. The method according to claim 12, wherein
one of the grooves penetrates the base substrate and the insulation layer, and a bottom of the groove is at a surface of the growth substrate close to the base substrate; or
one of the grooves penetrates the base substrate and the insulation layer, and the groove penetrates a part of the growth substrate; or
one of the grooves penetrates the base substrate, the insulation layer and the growth substrate.

19. The method according to claim 12, further comprising:
forming a superjunction structure in the growth substrate, the superjunction structure comprises n-type semiconductor structures and p-type semiconductor structures, and the n-type semiconductor structures and the p-type semiconductor structures are alternately distributed along a direction parallel to the growth substrate.

20. The method according to claim 12, wherein forming the grooves each penetrating at least one part of the base substrate comprises:
forming a protective layer on the side of the base substrate away from the growth substrate;
forming openings exposing the base substrate on the protective layer; and
etching the base substrate, using the protective layer with the openings as a mask, to form the grooves;
wherein after forming the grooves at a side of the base substrate away from the growth substrate, the method further comprising:
forming a heat-dissipation layer covering the inner wall of the grooves.
